(19) United States
(12) Patent Application Publication
(10) Pub. No.: US 2019/0355560 A1
(43) Pub. Date: Nov. 21, 2019

(54) PVD REACTOR WITH A FUNCTION OF ALIGNMENT IN COVERING AN UPPER COVER OF THE REACTOR

(71) Applicants: YING HSIEN CHENG, Taipei City (TW); Yuan Yuan Song, Taipei City (TW); Wei Chuan Chou, Taipei City (TW); Hsin-Chih Chiu, Taipei City (TW); Yu Hung Huang, Taipei City (TW); Kuei Chang Peng, Taipei City (TW)

(72) Inventors: YING HSIEN CHENG, Taipei City (TW); Yuan Yuan Song, Taipei City (TW); Wei Chuan Chou, Taipei City (TW); Hsin-Chih Chiu, Taipei City (TW); Yu Hung Huang, Taipei City (TW); Kuei Chang Peng, Taipei City (TW)

(21) Appl. No.: 15/985,681

(22) Filed: May 21, 2018

(51) Int. Cl. H01J 37/34; H01J 37/32; H01J 37/02; C23C 14/34

(52) U.S. Cl. CPC H01J 37/3417; C23C 14/34; H01J 37/023; H01J 37/32458

(57) ABSTRACT

A PVD reactor with a function of alignment in covering an upper cover includes a cavity having a first contact surface; an interior of the cavity having a metal isolation plate; an upper cover pivotally installed to the cavity; the upper cover having a second contact surface which is positioned corresponding to the first contact surface of the cavity; the upper cover being capable of being combined with a target; a plurality of semi-spherical recesses in the first contact surface of the cavity; and a plurality of semi-spherical protrusions in the second contact surface; when the upper cover covers upon the cavity, the plurality of semi-spherical protrusions will embed into the plurality of semi-spherical recesses.

### FIELD OF THE INVENTION

The present invention is related to PVD reactors, and in particular to a PVD reactor with a function of alignment in covering an upper cover of the reactor.

### BACKGROUND OF THE INVENTION

Physical vapor deposition (PVD) is a frequently used sputtering process, which is widely used semiconductor IC manufacturing process. By the process, target material is deposited on substrates or wafers, and other semiconductor materials. For example, producing of metal conductor wires, metal expansion hinder layers, and other plasma processes use such process.

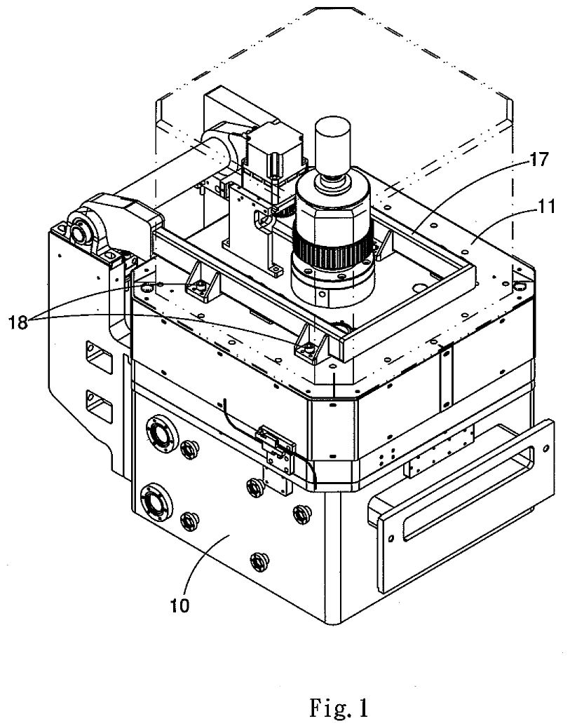

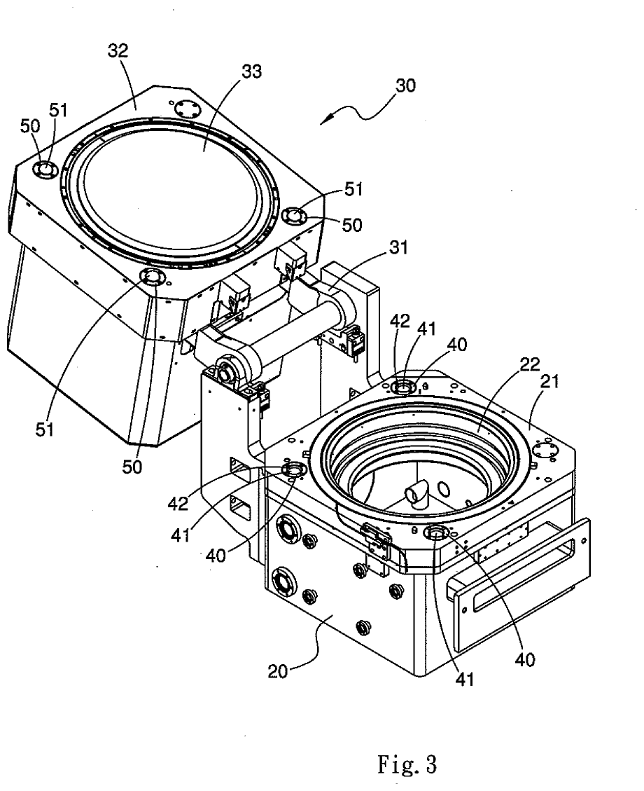

Referring to FIGS. 1 and 3, a generally used Physical vapor deposition (PVD) reactor is shown. The reactor includes a cavity 10 and an upper cover 11 pivotally installed to the cavity 10. A tray 12 is installed within the cavity 10 for supporting a base material (such as a wafer or a substrate). An inner side of the cavity 10 is formed with a metal isolation plate 14 which is used to prevent the sputtering material is sputtered to the metal wall of the cavity 10 in the sputtering process.

The upper cover 11 is combined with a target 15. An upper side of the target 15 is installed with a magnetic panel 16 to generate magnetic field. The gap between the isolation plate 14 and the target 15 must be finite for preventing that plasma generates between lateral sides of the target 15 and the isolation plate 14. This plasma will bomb the material of the back plate after the target 15 so as to pollute a plating film. In general, the gap is smaller than 2 mm. However, the isolation plate 14 cannot be in contact with the target 15 for preventing the current supplied to the target 15 to be grounded directly so that no plasma generates.

The operation of the PVD reactor is that a very high vacuum is needed in the cavity 10 and processing gas (such as argon) with proper amount is guided thereinto. Then DC current, pulse current or RF current is guided into the target 15 to ionize the gas into positive particle or negative electrons which will form as plasma between the target 15 and the base material 13. Rotation of the magnetic panel 16 will generate magnetic field so that electronic rotations within a specific area. Therefore, the positive particles in the plasma will collide the target 15 and deposits on the base material 13 to complete the sputtering process.

In PVD, the target 15 is a consumed material and thus it need to be updated. Furthermore the isolation plate 14 will form with film with a thickness. If the film is too thick to a specific thickness, it has the possibility that the isolation plate 14 will fall down, than the isolation plate 14 is necessary to be updated. As a result the upper cover 11 is necessary to be opened. Update of target 15 and maintenance of the reactor are also necessary to open the upper cover 11 and after treatment, the upper cover 11 is closed.

The upper cover 11 is combined to the cavity 10 by using a pivotal shaft 17. The pivotal shaft 17 is made by welding of tube material and thus it has a great mechanical error. The pivotal shaft 17 is combined to the cavity 10 by using a plurality of screws 18. The combination way also generates mechanical errors. However, it is required that the cavity 10 must have a very high vacuum. Combination between the upper cover 11 and the pivotal shaft 17 exist some margins, but when the upper cover 11 is turned through 90 degrees, it will have position errors due to the weight of the cover. Therefore, it is necessary that the upper cover 11 can exactly cover on the cavity.

Currently, two aligning bars 19 are inserted into the upper cover 11 and the cavity 10 for adjusting the upper cover 11 and the cavity 10 to be aligned. However, in this way, after the upper cover 11 covers on the cavity 10, then the two bars 19 are inserted thereinto, while in this process, a fine adjustment for adjusting the upper cover 11 is operated manually. This operation is time and labor wasted. Furthermore friction generated between the upper cover 11 and the cavity 10 so that cracks generate and some components destroys. Even, it is possible, that the aligning bars 19 cannot be withdrawn out.

### SUMMARY OF INVENTION

To resolve above mentioned defects in the prior art, the present invention provides a PVD reactor with a function of alignment in covering an upper cover, wherein when the upper cover covers upon the cavity, by contact of the first contact surface of the cavity with the second contact surface of the upper cover, the plurality of positioning blocks can be embedded into the plurality of positioning groove units precisely. The process of alignment becomes easily so that the time and labor hour is greatly reduced. Furthermore through many times of opening and covering of the upper cover, a reliable gap is still existed between the target and the isolation plate.

To achieve above object, the present invention provides a PVD reactor with a function of alignment in covering an upper cover includes a cavity having a first contact surface; an interior of the cavity having a metal isolation plate; an upper cover pivotally installed to the cavity; the upper cover having a second contact surface which is positioned corresponding to the first contact surface of the cavity; the upper cover being capable of being combined with a target; a plurality of semi-spherical recesses in the first contact surface of the cavity; and a plurality of semi-spherical protrusions in the second contact surface; when the upper cover covers upon the cavity, the plurality of semi-spherical protrusions will embed into the plurality of semi-spherical recesses.

### DETAILED DESCRIPTION OF THE INVENTION

FIG. 1 is a schematic view showing a prior art PVD reactor.

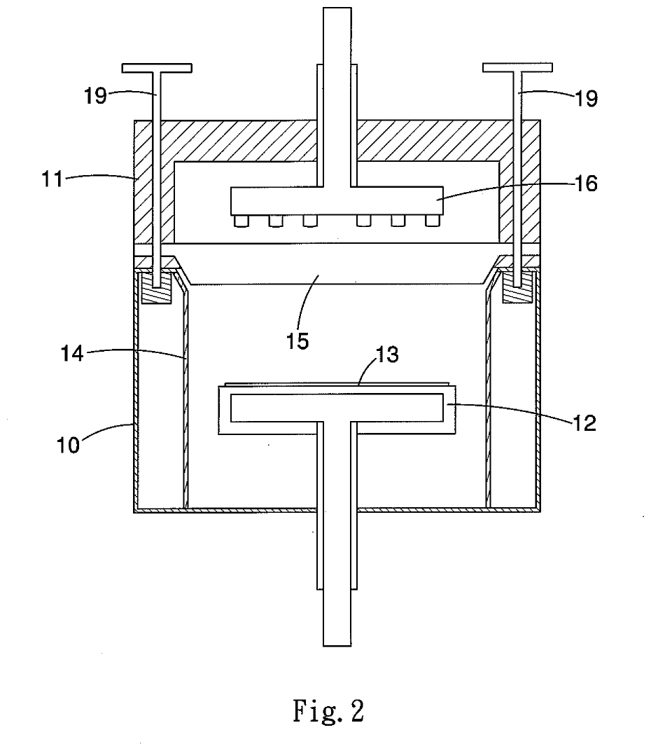

FIG. 2 is a schematic view showing the alignment operation of the upper cover to the cavity in the prior art.

FIG. 3 is a perspective schematic view showing that the upper cover is opened in the present invention.

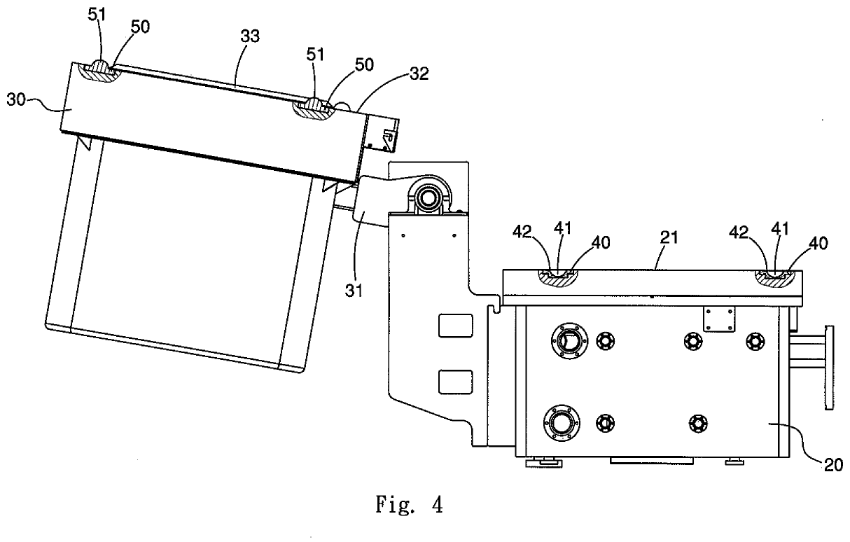

FIG. 4 is a lateral and partial cross sectional schematic view showing the state that the upper cover is opened in the present invention.

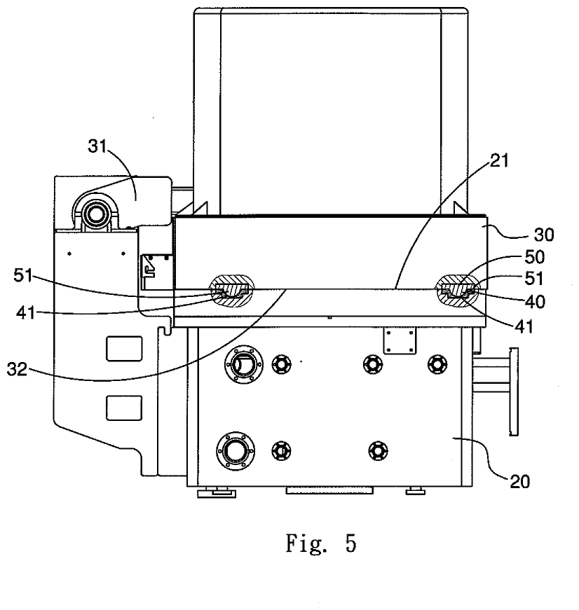

FIG. 5 is a lateral and partial cross sectional schematic view showing the state that the upper cover is closed in the present invention.

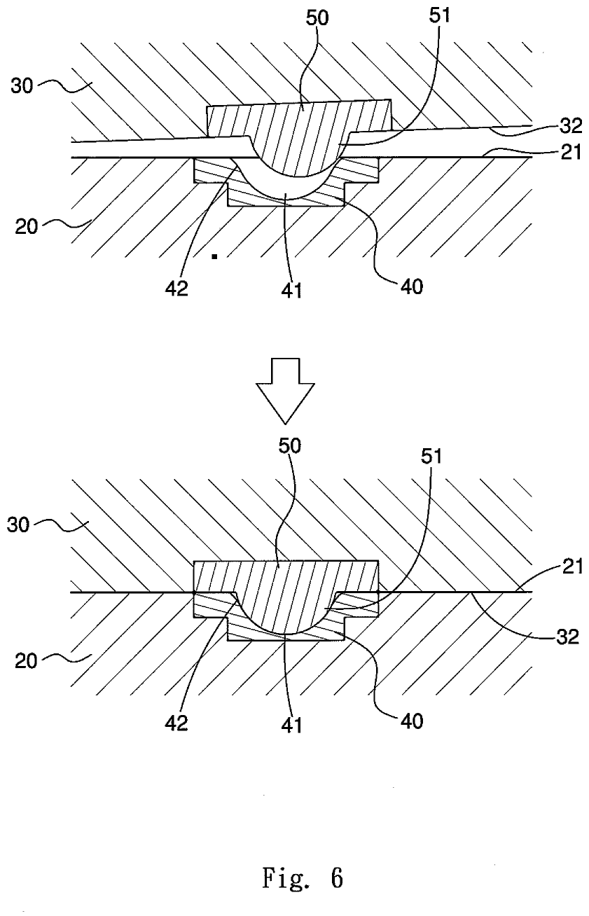

FIG. 6 is an enlarged schematic view showing the auto alignment operation in the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

With reference to FIGS. 3 to 6, the structure of the present invention is illustrated. The present invention includes the following elements.

A cavity 20 has a first contact surface 21. An interior of the cavity 20 has a metal isolation plate 22 for preventing metal atoms to sputter to metal inner wall of the cavity 20 in sputtering process.

An upper cover 30 is pivotally installed to the cavity 20 by using a pivotal shaft 31 so that the upper cover 30 is openable and coverable with respect to the cavity 20. The upper cover 30 has a second contact surface 32 which is positioned corresponding to the first contact surface 21 of the cavity 20. The upper cover 30 serves to be combined with a target 33.

A plurality of positioning groove units 40 are combined in the first contact surface 21 of the cavity 20. Each positioning groove unit 40 has a semi-spherical recess 41.

A plurality of positioning blocks 50 are combined to the second contact surface 32 of the upper cover 30. Each positioning block 50 has a semi-spherical protrusion 51. When the upper cover 30 covers upon the cavity 20, the plurality of semi-spherical protrusions 51 will embed into the plurality of semi-spherical recesses 41.

With reference to FIG. 6, it is illustrated that an opening of each semi-spherical recess 41 is formed with a large cambered guide angle 42 for guiding a respective semi-spherical protrusion 51 to embed thereinto.

In this embodiment, there are three positioning groove units 40 and three positioning blocks 50. The three positioning groove units 40 are at three corners of the first contact surface 21 and the three positioning blocks 50 are at three corners of the second contact surface 32 at positions corresponding to those of the positioning groove units 40.

However, in another case, there are two positioning groove units 40 and two positioning blocks 50. The two positioning groove units 40 are at two corners of the first contact surface 21 and the two positioning blocks 50 are at two corners of the second contact surface 32 at positions corresponding to those of the positioning groove units 40.

In a further case, there are four positioning groove units 40 and four positioning blocks 50. The four positioning groove units 40 are at four corners of the first contact surface 21 and the four positioning blocks 50 are at four corners of the second contact surface 32 at positions corresponding to those of the positioning groove units 40.

The present invention provides an auto aligning structure for combining an upper cover 30 to the cavity 20 in a physical vapor deposition reactor. When the upper cover 30 covers upon the cavity 20, by contact of the first contact surface 21 of the cavity 20 with the second contact surface 32 of the upper cover 30, the plurality of positioning blocks 50 can be embedded into the plurality of positioning groove units 40 precisely. The process of alignment becomes easily so that the time and labor hour is greatly reduced. Furthermore through many times of opening and covering of the upper cover 30, a reliable gap is still existed between the target 33 and the isolation plate 22.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A PVD reactor with a function of alignment in covering an upper cover, comprising:
a cavity having a first contact surface; an interior of the cavity having a metal isolation plate;
an upper cover pivotally installed to the cavity; the upper cover having a second contact surface which is positioned corresponding to the first contact surface of the cavity; and the upper cover being combinable with a target;
a plurality of semi-spherical recesses in the first contact surface of the cavity; and
a plurality of semi-spherical protrusions in the second contact surface; when the upper cover covers upon the cavity, the plurality of semi-spherical protrusions will embed into the plurality of semi-spherical recesses.

2. The PVD reactor with a function of alignment in covering an upper cover as claimed in claim 1, wherein an opening of each semi-spherical recess has an enlarge cambered guide angle for guiding the semi-spherical protrusion into the semi-spherical recess.

3. The PVD reactor with a function of alignment in covering an upper cover as claimed in claim 1, wherein there are three positioning groove units and three positioning blocks; the three positioning groove units are at three corners of the first contact surface and the three positioning blocks are at three corners of the second contact surface at positions corresponding to those of the positioning groove units.

4. The PVD reactor with a function of alignment in covering an upper cover as claimed in claim 1, wherein there are two positioning groove units and two positioning blocks; the two positioning groove units are at two corners of the first contact surface and the two positioning blocks are at two corners of the second contact surface at positions corresponding to those of the positioning groove units.

5. The PVD reactor with a function of alignment in covering an upper cover as claimed in claim 1, wherein there are four positioning groove units and four positioning blocks; the four positioning groove units are at four corners of the first contact surface and the four positioning blocks are at four corners of the second contact surface at positions corresponding to those of the positioning groove units.

6. The PVD reactor with a function of alignment in covering an upper cover as claimed in claim 1, wherein the upper cover is pivotally installed to the cavity by using a pivotal shaft so that the upper cover is openable and coverable with respect to the cavity.

7. The PVD reactor with a function of alignment in covering an upper cover as claimed in claim 1, wherein a plurality of positioning groove units are combined in the first contact surface of the cavity; each positioning groove unit having one of the semi-spherical recesses; a plurality of positioning blocks combined to the second contact surface of the upper cover; each positioning block having one of the semi-spherical protrusions; when the upper cover covers upon the cavity, the plurality of semi-spherical protrusions will embed into the plurality of semi-spherical recesses.
